(19) United States
(12) Patent Application Publication
(10) Pub. No.: US 2009/0184325 A1
(43) Pub. Date: Jul. 23, 2009

(54) METHOD OF PLANARIZING SUBSTRATE, ARRAY SUBSTRATE AND METHOD OF MANUFACTURING ARRAY SUBSTRATE USING THE SAME

(75) Inventors: Jeong-Min PARK, Seoul (KR); Doo-Hee JUNG, Seoul (KR); Hi-Kuk LEE, Yongin-si (KR); Young-Wook LEE, Suwon-si (KR)

Correspondence Address: CANTOR COLBURN, LLP, 20 Church Street, 22nd Floor, Hartford, CT, 06103, US

(73) Assignee: Samsung Electronic Co., Ltd., Suwon-si (KR)

(21) Appl. No.: 12/331,044

(22) Filed: Dec. 9, 2008

(30) Foreign Application Priority Data
Jan. 21, 2008 (KR) 2008-6160

(51) Int. Cl. H01L 33/00; B44C 1/22; H01L 21/336

(52) U.S. Cl. 257/72; 216/38; 438/34; 257/E33.053; 257/E21.414

(57) ABSTRACT

A method of planarizing a substrate. An organic layer is formed on a base substrate to cover a metal line formed on the base substrate. A portion of the organic layer is removed to form a pre-planarization layer exposing the metal layer, so that a surface of the base substrate having the metal line is planarized. The pre-planarization layer is cured to flow toward a side surface of the metal line to form a planarization layer making contact with the side surface of the metal line. Therefore, a stepped portion between the base substrate and the metal line can be minimized or substantially eliminated, thereby increasing the surface uniformity of a subsequent layer, thereby improving the reliability of the manufacturing process.

This application claims priority to Korean Patent Application No. 2008-6160, filed on Jan. 21, 2008, and all the benefits accruing therefrom under 35 U.S.C. §119, the contents of which in its entirety are herein incorporated by reference.

### BACKGROUND OF THE INVENTION

1. Field of the Invention

This disclosure relates to a method of planarizing a substrate, an array substrate, and a method of manufacturing an array substrate using the same.

2. Description of the Related Art

A liquid crystal display (“LCD”) panel, in general, includes an array substrate, an opposite substrate, and a liquid crystal layer. The array substrate can include a switching element for driving a pixel region. The opposite substrate can face the array substrate. The liquid crystal layer can be interposed between the array substrate and the opposite substrate. When an electric field is applied to the liquid crystal layer of the LCD panel, the light transmittance of the liquid crystal layer is changed so that an image is displayed on the LCD panel.

The array substrate includes a plurality of gate and data lines, a plurality of thin-film transistors (“TFTs”) which are the switching elements and a pixel electrode on each of the TFTs electrically connected to each of the TFTs. The gate lines extend in a direction different from the data lines. Each of the TFTs includes a gate electrode electrically connected to one of the gate lines, a channel pattern formed on a gate insulation layer, the gate insulation layer covering the gate electrode, a source electrode on the channel pattern to be partially overlapped with the gate electrode, and a drain electrode on the channel pattern to be partially overlapped with the gate electrode. The drain electrode is spaced apart from the source electrode.

In order to manufacture the array substrate, the gate insulation layer and a silicon layer for forming the channel pattern can be disposed on a base substrate having the gate lines and the gate electrode, in sequence. The gate insulation layer and the silicon layer can be patterned.

The gate insulation layer and the silicon layer can be disposed on a gate pattern, the gate pattern including the gate line and the gate electrode, using a chemical vapor deposition (“CVD”) method. A portion of the gate insulation layer and the silicon layer can become stacked to form a stepped portion between a side of the gate pattern and the base substrate. The size of the stacked structure can be proportional to the number of layers disposed on the gate pattern. Thus, an upper layer in a stacked structure can be larger than a lower layer.

The surface uniformity of a gate insulation layer and a silicon layer that are stacked on a gate pattern can be decreased by the stacked structure. Thus, electrons can concentrate on the stacked structure to form a static charge. Also, a source metal layer disposed on the silicon layer can be disconnected from electrical communication, thereby deteriorating the reliability of the manufacturing process.

### BRIEF SUMMARY OF THE INVENTION

The above described and other drawbacks are alleviated by a method of planarizing a substrate, wherein the method can substantially prevent formation of a stacked structure, thus substantially preventing formation of a stepped portion.

Also disclosed is an array substrate having improved reliability.

Also disclosed is a method of manufacturing an array substrate using the method of planarizing the substrate.

Disclosed herein is a method of planarizing a substrate, the method including: disposing an organic layer on a base substrate, the base substrate including a metal line; removing a portion of the organic layer to expose the metal line and form a pre-planarization layer; and flowing the pre-planarization layer toward a side surface of the metal line to dispose a planarization layer in intimate contact with the side surface of the metal line so that a surface of the base substrate having the metal line is planarized.

Also disclosed herein is an array substrate including a gate pattern, a planarization layer, a gate insulation layer, a semiconductor pattern, a source pattern, a passivation layer and a pixel electrode.

Further disclosed herein is an array substrate including: a gate pattern on a base substrate, the gate pattern including a gate line and a gate electrode in electrical communication with the gate line; a planarization layer adjacent to and in intimate contact with the gate pattern, the planarization layer having a greater thickness than the gate pattern to planarize a surface of the base substrate having the gate pattern. a gate insulation layer on the gate pattern and the planarization layer, the gate insulation layer being in intimate contact with an upper surface of the gate pattern and the planarization layer; a semiconductor pattern on the gate insulation layer; a source pattern on the gate insulation layer, the source pattern including: a data line extending in a direction different from the direction of the gate line; a source electrode on the semiconductor pattern and in electrical communication with to the data line; and a drain electrode on the semiconductor pattern and spaced apart from the source electrode; a passivation layer on the source pattern, the passivation layer having a contact hole through which the drain electrode is partially exposed; and a pixel electrode is on the passivation layer, the pixel electrode being in electrical communication with to the drain electrode through the contact hole.

Also disclosed is a method of manufacturing an array substrate, the method including: disposing a gate pattern on a base substrate, and the gate pattern including a gate line and a gate electrode in electrical communication with the gate line; disposing an organic layer on the base substrate, the base substrate including the gate pattern, the organic layer substantially covering the gate pattern; disposing a pre-planarization layer is by removing a portion of the organic layer to expose an upper surface and a side surface of the gate pattern, the pre-planarization layer planarizing a surface of the base substrate; flowing the pre-planarization layer toward the side surface of the gate pattern to dispose a planarization layer, the planarization layer being in intimate contact with the side surface of the gate pattern; disposing a source pattern is formed on the base substrate, the base substrate having the gate pattern and the planarization layer, the source pattern including a data line extending in a direction different from the gate line, a source electrode in electrical communication with the data line, and a drain electrode spaced apart from the source electrode; and disposing a pixel electrode on the base substrate, the base substrate having the source pattern, the pixel electrode being in electrical communication with the drain electrode.

Also disclosed is a method of planarizing a substrate, an array substrate, and the method of manufacturing the array substrate using the same, wherein the stepped portion between the base substrate and a metal line is minimized to prevent a stacked structure from being formed on a side surface of the metal layer and the base substrate. Thus, the surface uniformity of the subsequent layer can be improved, and the reliability of the array substrate and the method of manufacturing the array substrate can be enhanced.

### BRIEF DESCRIPTION OF THE DRAWINGS

The above and other advantages will become more apparent by describing in detail exemplary embodiments thereof with reference to the accompanying drawings, in which:

FIGS. 1 to 3 are cross-sectional views illustrating an exemplary embodiment of a method of planarizing a substrate;

FIG. 4 is a scanning electron microscope (“SEM”) image illustrating a portion ‘A’ of FIG. 2;

FIG. 5 is a SEM image illustrating a portion ‘B’ of FIG. 3;

FIG. 6 is a cross-sectional view illustrating a substrate shown in FIG. 5;

FIG. 7 is a cross-sectional view illustrating an exemplary embodiment of a method of planarizing a substrate;

FIG. 8 is a cross-sectional view illustrating an exemplary embodiment of a method of planarizing a substrate;

FIG. 9 is a plan view illustrating an exemplary embodiment of an array substrate;

FIG. 10 is a cross-sectional view taken along a line I-I′ shown in FIG. 9; and

FIGS. 11 to 17 are cross-sectional views illustrating an exemplary embodiment of a method of manufacturing the array substrate shown in FIG. 10.

### DETAILED DESCRIPTION OF THE INVENTION

The embodiments are described more fully hereinafter with reference to the accompanying drawings, in which embodiments are shown. This disclosure can, however, be embodied in many different forms and should not be construed as limited to the embodiments set forth herein. Rather, these embodiments are provided so that this disclosure will be thorough and complete, and will fully convey the scope of the disclosure to those skilled in the art. In the drawings, the size and relative sizes of layers and regions can be exaggerated for clarity.

It will be understood that when an element or layer is referred to as being “on,” “connected to” or “coupled to” another element or layer, it can be directly on, connected or coupled to the other element or layer or intervening elements or layers can be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. can be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of this disclosure.

Spatially relative terms, such as “beneath,” “below,” “lower,” “above,” “upper” and the like, can be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device can be otherwise oriented (rotated 90 degrees or at other orientations) and the spatially relative descriptors used herein interpreted accordingly.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments are described herein with reference to cross-section illustrations that are schematic illustrations of idealized embodiments (and intermediate structures). As such, variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation can result in some implantation in the region between the buried region and the surface through which the implantation takes place. Thus, the regions illustrated in the figures are schematic in nature and their shapes are not intended to illustrate the actual shape of a region of a device and are not intended to limit the scope of this disclosure.

Unless otherwise defined, all terms (including technical and scientific terms) used herein have the same meaning as commonly understood by one of ordinary skill in the art. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, the embodiments will be described in detail with reference to the accompanying drawings.

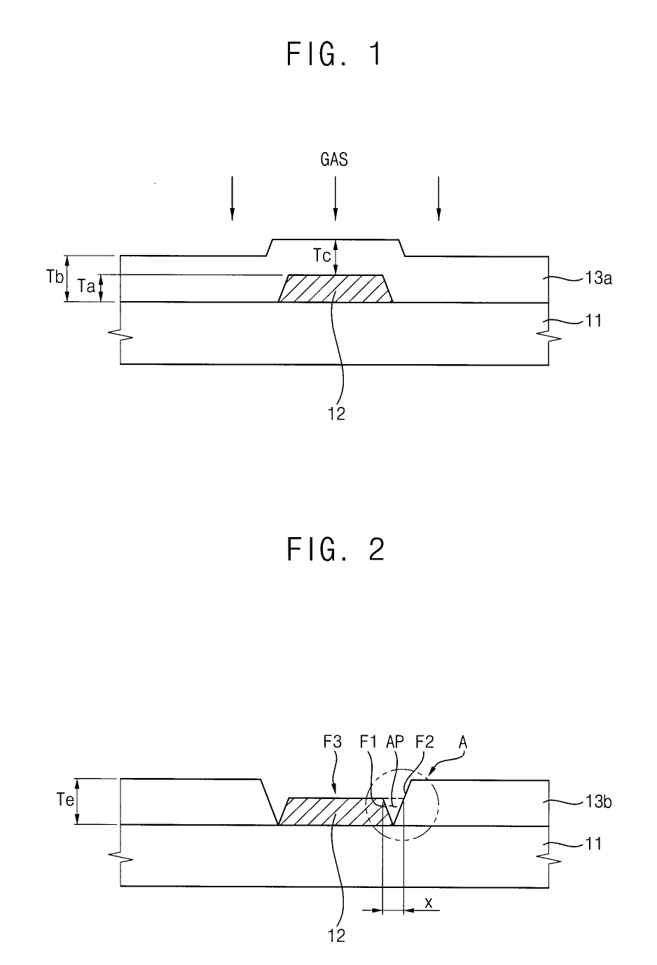

FIGS. 1 to 3 are cross-sectional views illustrating a method of planarizing a substrate in accordance with an embodiment.

Referring to FIG. 1, a metal line 12 can be disposed on a base substrate 11. An organic layer 13a can be disposed on the base substrate 11, the base substrate 11 having the metal line 12.

An exemplary method of forming a metal line can include disposing a metal layer (not shown) on the base substrate 11, and the metal layer can patterned to form the metal line 12. Exemplary methods of disposing the metal layer on the base substrate 11 include sputtering, vapor deposition, or the like. Exemplary methods to pattern the metal layer to form a metal line 12 include photolithography, or the like. The metal line 12 can be disposed on the base substrate 11 at a first thickness Tₐ. For example, the first thickness Tₐ can be about 0.1 μm to about 10 μm, specifically about 0.5 μm to about 5 μm, more specifically 1 μm to about 4 μm.

The organic layer 13a can be disposed on the base substrate 11 to substantially cover the metal line 12. The organic layer 13a can be in intimate contact with the metal line 12 and the base substrate 11. The organic layer 13a can be disposed on the base substrate 11 at a second thickness T_{b}, and the metal line 12 can have a third thickness T_{c}. The second thickness T_{b} can be greater than the first thickness Tₐ, and the second thickness T_{b} can be greater than the third thickness T_{c}. A difference between the second thickness T_{b} and the third thickness T_{c} can be greater than the first thickness Tₐ. Although the organic layer 13a may be removed by the third thickness T_{c}, the organic layer 13a can remain on the base substrate 11 at a thickness greater than the first thickness Ta. Alternatively, at least a portion of the organic layer may remain on the metal line 12. Also, the organic layer may remain on at least a portion of the metal line 12.

An organic material can be disposed on the base substrate 11, the base substrate having the metal line 12, to form the organic layer 13a. Exemplary methods of disposing the organic material include spin coating, slit coating, dip coating, spray coating, drop casting, electrostatic painting, or the like, or a combination comprising at least one of the foregoing coating methods. In an embodiment, the organic material can be coated on the base substrate 11, the base substrate 11 having the metal line 12. The organic material can be photosensitive or light-insensitive.

Exemplary methods of removing the organic layer 13a include dry etching, wet etching, or the like. In an exemplary embodiment, the removing method can be an anisotropic etching process

Referring to FIG. 2, the metal line 12 can be exposed using a dry etching process to dispose a pre-planarization layer 13b that planarizes the base substrate 11 having the metal line 12.

In an embodiment, the thickness of the organic layer 13a can be decreased, using a dry etching process, to a constant thickness using an etching gas. The constant thickness can be a third thickness T_{c}. Thus, disposing the pre-planarization layer 13b can expose an upper surface F3 and a side surface F1 of the metal line 12. When the thickness of the organic layer 13a is decreased using the dry etching process to the third thickness Tc, the pre-planarization layer 13b, in a region between the metal line 12 and the base substrate 11, can be substantially equal to a fourth thickness Tₑ. The fourth thickness Tₑ can be substantially equal to a thickness determined as the second thickness T_{b} less the third thickness T_{c}. The fourth thickness Tₑ of the pre-planarization layer 13b can be greater than the first thickness Tₐ of the metal line 12.

The side surface F1 of the metal line 12 can be spaced apart from the side surface F2 of the pre-planarization layer 13b, wherein the side surface F2 faces the side surface F1 of the metal line 12. The side surface F1 of the metal line 12 can form a positive angle with respect to the base substrate 11, and the side surface F2 of the pre-planarization layer 13b can form a negative angle with respect to the base substrate 11 after the dry etching process. Thus, the side surface F1 of the metal line 12 can be spaced apart from the side surface F2 of the pre-planarization layer 13b to form a separation part AP. A first distance x is defined by a maximum distance between the side surface F1 of the metal line 12 and the side surface F2 of the pre-planarization layer 13b.

Referring to FIG. 3, the pre-planarization layer 13b can flow to fill the separation part AP by curing the pre-planarization layer 13b.

When the pre-planarization layer 13b is cured, the side surface F2 of the pre-planarization layer 13b can flow toward the side surface F1 of the metal line 12 so that the pre-planarization layer 13b is in intimate contact with the side surface F1 of the metal line 12, thereby disposing the planarization layer 13c. An inclined surface F5 can be inclined from a planarization surface F4 toward the side surface F1 of the metal line 12 by the curing. The planarization surface F4 can be substantially parallel with the surface of the base substrate 11.

In an embodiment, the curing process can include heat-treating a base substrate 11 having the pre-planarization layer 13b. The base substrate 11 having the pre-planarization layer 13b can be heated at a temperature of about 100° C. to about 500° C., specifically about 180° C. to about 250° C., more specifically about 200° C. to about 230° C. The heat-treated pre-planarization layer 13b can be fluid, and the organic material can flow toward and/or into the separation part AP. Thus, the pre-planarization layer 13b can contact the side surface F1 of the metal line 12 to fill the separation part AP, thereby disposing the planarization layer 13c.

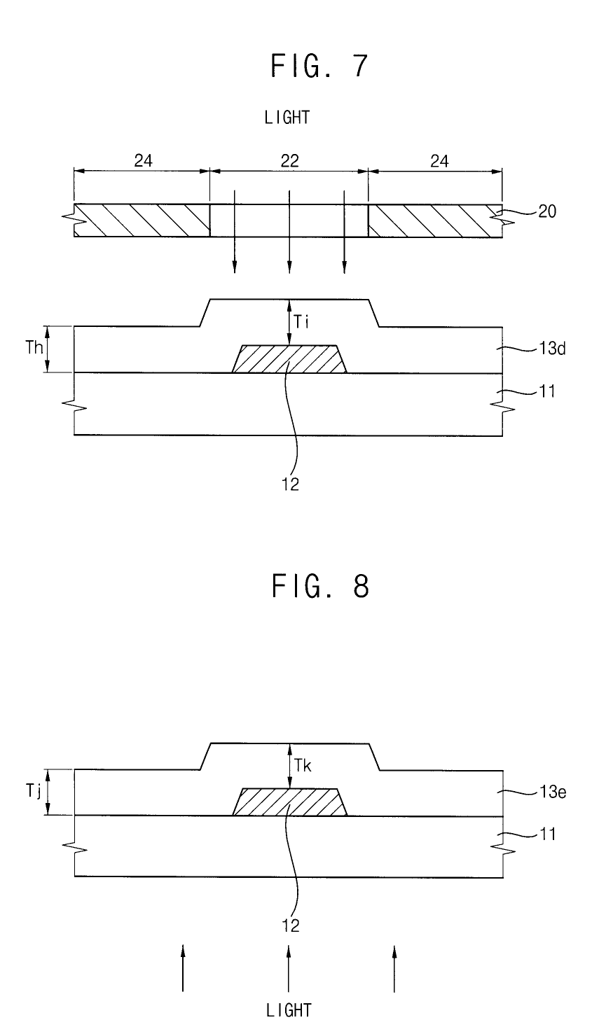

Alternatively, ultraviolet light can be irradiated onto the base substrate 11 having the pre-planarization layer 13b so that the organic material of the pre-planarization layer 13b is fluid, is which case the organic material of the pre-planarization layer 13b can flow toward and/or into the separation part AP. The curing of the pre-planarization layer 13b will be explained with reference to FIG. 6.

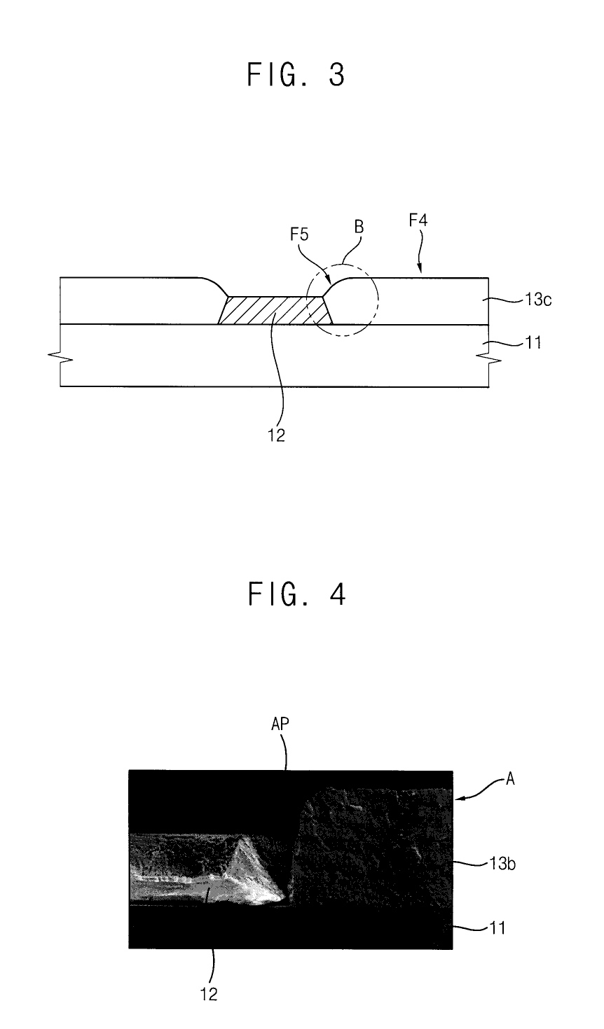

FIG. 4 is a scanning electron microscope (“SEM”) image illustrating a portion ‘A’ of FIG. 2.

Referring to FIGS. 2 and 4, the side surface F1 of the metal line 12 can be spaced apart from the side surface F2 of the pre-planarization layer 13b to form the separation part AP. When a subsequent layer is disposed on the separation part AP, the surface uniformity of the subsequent layer on the base substrate 11 can be deteriorated.

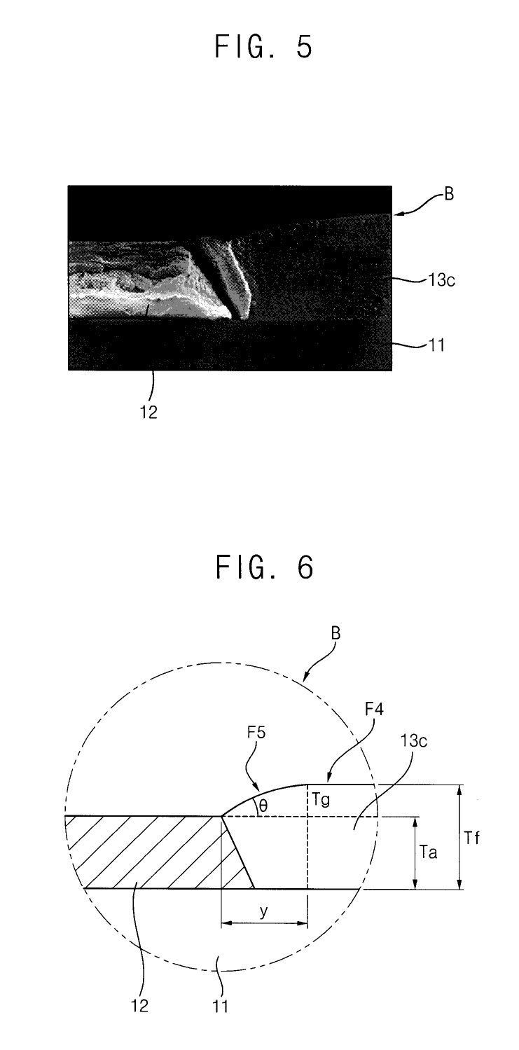

FIG. 5 is a SEM image illustrating a portion ‘B’ of FIG. 3.

Referring to FIGS. 3 and 5, the pre-planarization layer 13b can be cured so that the organic material of the pre-planarization layer 13b flows toward the separation part AP to dispose the planarization layer 13c. When the pre-planarization layer 13b is cured, the pre-planarization layer 13b can contact the side surface F1 of the metal line 12, so that the planarization layer 13c is smoothly connected to the metal line 12 disposed on the base substrate 11.

A portion of the planarization layer 13c of FIG. 5 on the side surface F1 of the metal line 12 can have different chemical and physical characteristics than a remaining portion of the planarization layer 13c. The organic material can overflow on the portion of the planarization layer 13c on the side surface F1 of the metal line 12. The inclined surface F5 of the planarization layer 13c can form between the overflow region and the remaining portion of the planarization layer 13c, which corresponds to the flat surface F4.

FIG. 6 is a cross-sectional view illustrating a substrate shown in FIG. 5.

Referring to FIG. 6, the cured pre-planarization layer 13b can flow a flow length of a second distance y to contact the side surface F1 of the metal line 12, thereby disposing the planarization layer 13c. The second distance y is a horizontal distance between an end portion at which the upper surface F3 makes contact with the side surface F1 of the metal line 12 and an interface between the inclined surface F5 and the planarization surface F4. The second distance y can be substantially equal to the first distance x.

The cured pre-planarization layer 13b can contact the side surface F1 of the metal line 12 to fill the separation part AP. Thus, the inclined surface F4, having a flowing angle θ, is formed. The flowing angle θ can be selected to minimize a stepped portion between the first thickness Tₐ of the metal line 12 and the fourth thickness Tₑ of the pre-planarization layer 13b to planarize the surface of the base substrate 11 having the metal line 12. When the fourth thickness Tₑ is greater than the first thickness Tₐ, and the flowing angle θ is less than or equal to about 10 degrees, specifically less or equal to about 5 degrees, more specifically less than or equal to about 0.1 degrees, the organic material can substantially cover the upper surface F3 of the metal line 12. When the flowing angle θ is greater than or equal to about 20 degrees, specifically greater than or equal to about 40 degrees, more specifically greater than or equal to about 60 degrees, the separation part AP can be partially filled or can not be filled by the organic material, and the stepped portion between the upper surface F3 of the metal line 12 and the inclined surface F5 of the planarization layer 13c can be increased. Thus, the flowing angle θ can be between about 0.01 degrees to about 89 degrees, specifically about 0.1 degrees to about 60 degrees, more specifically about 1 degree to about 50 degrees. For example, when the flowing angle θ is greater than 60 degrees, a step coverage of the pre-planarization layer 13b may be deteriorated.

The fifth thickness T_{f} that is a distance between the surface of the base substrate 11 and the planarization surface F4 can be greater than the first thickness Tₐ of the metal line 12. The fifth thickness T_{f} can be calculated by the following Equation 1 with reference to the first thickness Tₐ, the second distance y, which is the flowing distance and the flowing angle θ:

T_{f}=Tₐ+yx tan θ (1)

The fifth thickness T_{f} of the planarization layer 13c can be greater than the first thickness Tₐ of the metal line 12 by a sixth thickness T_{g} that is equal to tangent θ multiplied by the second distance y.

As shown in FIG. 14, the organic material can overflow into the separation part AP, to form the inclined surface F5 that extends from the overflowed region toward the planarization surface F4, wherein the flowing angle θ and the first thickness Tₐ satisfy the Equation 1.

The pre-planarization layer 13b can be disposed and cured to minimize a stepped portion between the base substrate 11 and the metal line 12. Thus, a subsequent layer can be disposed on the metal line 12 while substantially avoiding forming a stacked portion on the stepped portion between the side surface F1 of the metal line 12 and the base substrate 11. Thus, the surface uniformity of the subsequent layer can be increased, thereby improving the reliability of the substrate and the method of manufacturing the substrate.

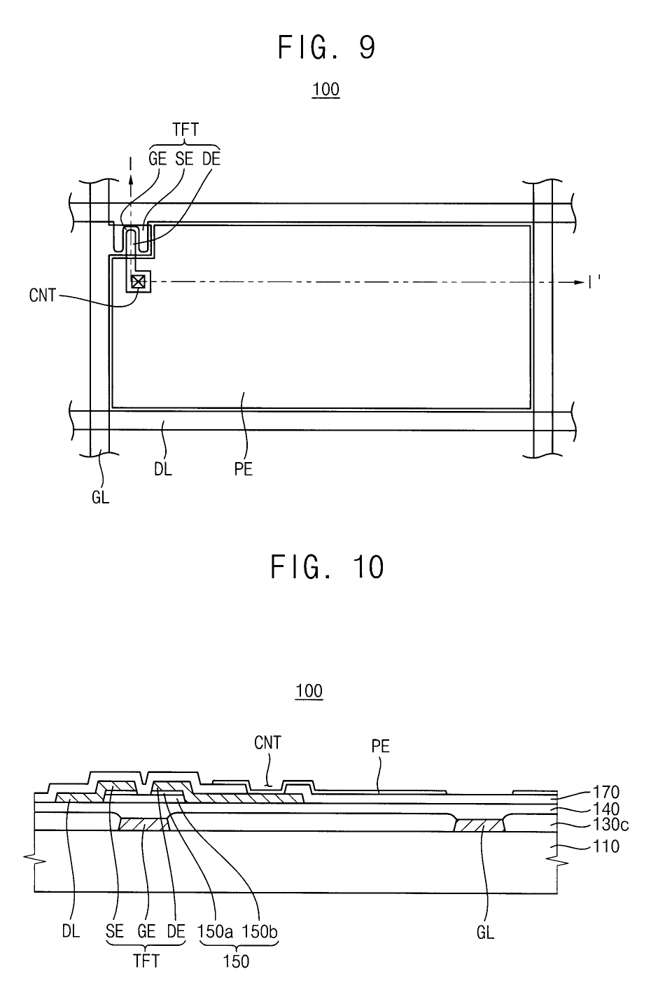

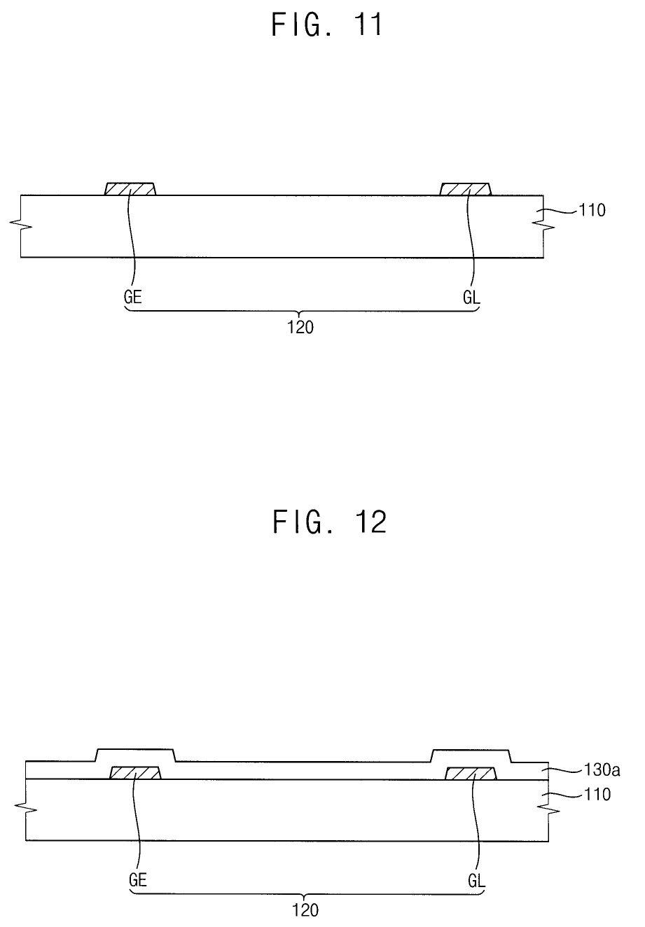

Hereinafter, processes for disposing a planarization layer using organic layers will be explained with reference to FIGS. 7 and 8. In FIGS. 7 and 8, the organic layer is represented by reference numerals of 13d and 13e, respectively. Exemplary materials for the organic layer includes a positive photoresist, a negative photoresist, or the like. The processes for forming a planarization layer and curing the planarization layer can be substantially the same as those described in conjunction with FIGS. 2 and 3. Thus, the same reference numerals will be used to refer to the same or like parts as those described in FIGS. 2 and 3 and redundant explanation concerning the above elements will be omitted.

FIG. 7 is a cross-sectional view illustrating a method of planarizing a substrate in accordance with an embodiment.

Referring to FIG. 7, a metal line 12 can be disposed on a base substrate 11, and an organic layer 13d can be disposed on the base substrate 11 having the metal line 12. The organic layer 13d can include a photoresist. In an exemplary embodiment, the organic layer 13d can include a positive photoresist. A developing agent can remove an exposed portion of the positive photoresist, and a non-exposed portion of the positive photoresist can remain on the base substrate 11.

A thickness Tᵢ of the organic layer 13d disposed on the metal line 12 can be substantially equal to a thickness of the organic layer 13d where it contacts the base substrate 11. In an embodiment, the organic layer 13d on the metal line 12 can be selectively removed, so that the thickness Tᵢ of the organic layer 13d on the metal line 12 can be substantially same as a thickness Tₕ of the organic layer 13d where it contacts the base substrate 11. In an alternative embodiment, the thickness Tᵢ of the organic layer 13d on the metal line 12 can be different from the thickness Tₕ of the organic layer 13d where it contacts the base substrate 11. The thickness Tₕ of the organic layer 13d where it contacts the base substrate 11 can be greater than the first thickness Tₐ of the metal line 12. In an exemplary embodiment, the thickness Tₕ of the organic layer 13d where it contacts the base substrate 11 can be substantially equal to the fourth thickness Tₑ of a pre-planarization layer 13b.

A mask 20 can be disposed on the base substrate 11, the base substrate 11 having the organic layer 13d, and light can be irradiated onto the organic layer 13d through the mask 20. The mask 20 can include a transmission portion 22 and a blocking portion 24. The transmission portion 22 can be disposed on the metal line 12. When the organic layer 13d remains on a stepped portion between the metal line 12 and the base substrate 11, a planarization layer that will be disposed through a subsequent process can substantially cover the metal line 12, or the organic layer 13d can form a stepped portion along the metal line 12. Thus, the width of the transmission portion 22 can be selected so that a surface F1 of the metal line 12 and a side surface F2 of the metal line 12 are exposed after a developing process. For example, the width of the transmission portion 22 may be greater than the width of the metal line 12.

Referring to FIGS. 2, 3 and 7, the exposed organic layer 13d can be developed so that the portion of the organic layer 13d on the metal line 12 can be selectively removed to leave the unexposed portion of the organic layer 13d and the metal line 12 on the base substrate 11. Thus, the pre-planarization layer 13b and the metal line 12 can be disposed on the base substrate 11 to planarize the metal line 12. The pre-planarization layer 13b can be cured to substantially fill a separation part AP between the side surface F1 of the metal line 12 and the side surface F2 of the pre-planarization layer 13b.

In an embodiment, the organic layer 13d can include a negative photoresist. An exposed portion of the negative photoresist can remain on the base substrate 11, and a developing agent can remove a non-exposed portion of the negative photoresist. When the organic layer 13d includes the negative photoresist, the blocking portion of the mask 20 can be disposed on the metal line 12. When the exposed organic layer 13d is developed, the portion of the organic layer 13d on the metal line 12 can be selectively removed, and the remainder of the organic layer 13d on the base substrate 11 can remain on the base substrate 11. Thus, the pre-planarization layer 13b can be disposed, and the pre-planarization layer 13b can be cured to substantially fill the separation part AP between the side surface F1 of the metal line 12 and the side surface F2 of the pre-planarization layer 13b.

FIG. 8 is a cross-sectional view illustrating a method of planarizing a substrate in accordance with an embodiment.

Referring to FIG. 8, a metal line 12 can be disposed on a base substrate 11, and an organic layer 13e can be disposed on the base substrate 11, the base substrate 11 having the metal line 12. The organic layer 13e can include a photoresist. Exemplary materials for the organic layer 13e include a positive photoresist, a negative photoresist, or the like. The organic layer 13e of the metal line 12 can be selectively removed, so that a thickness Tₖ of a portion of the organic layer 13e on the metal line 12 can be substantially the same as a thickness Tⱼ of a portion of the organic layer 13e that contacts the base substrate 11. Alternatively, the thickness Tₖ of the portion of the organic layer 13e on the metal line 12 can be different from the thickness Tⱼ of the portion of the organic layer 13e that contacts the base substrate 11. The thickness Tj of the portion of the organic layer 13e that contacts the base substrate 11 can be greater than the first thickness Tₐ of the metal line 12. In an exemplary embodiment, the thickness Tⱼ of the portion of the organic layer 13e that contacts the base substrate 11 can be substantially equal to the fourth thickness Tₑ of a pre-planarization layer 13c. Light can be irradiated onto a rear surface of the base substrate 11, which can be opposite the organic layer 13e, to expose the organic layer 13e using a rear surface exposing method.

Referring to FIGS. 2, 3 and 8, the metal line 12 can function as a mask that blocks the light so that the light is not irradiated onto the organic layer 13e. A developing agent can remove a portion of the organic layer 13e on the metal line 12.

The light can pass through the base substrate 11 and not the metal line 12, thus can irradiate a remainder of the organic layer 13e, so that the exposed negative photoresist is solidified and the remainder of the organic layer 13e remains on the base substrate 11. Thus, the pre-planarization layer 13b and exposed metal line 12 can be disposed on the base substrate 11 to planarize the metal line 12. The side surface F1 of the metal line 12 can have a tapered shape so that the side surface F1 of the metal line 12 is exposed by the pre-planarization layer 13b. Exemplary methods of disposing the side surface F1 include wet etching, dry etching, or the like, or a combination comprising at least one of the foregoing methods. The pre-planarization layer 13b can be cured to substantially fill a separation part AP between the side surface F1 of the metal line 12 and the side surface F2 of the pre-planarization layer 13b.

Hereinafter, a method of manufacturing an array substrate using the above-described method of planarizing the array substrate and the substrate will be explained.

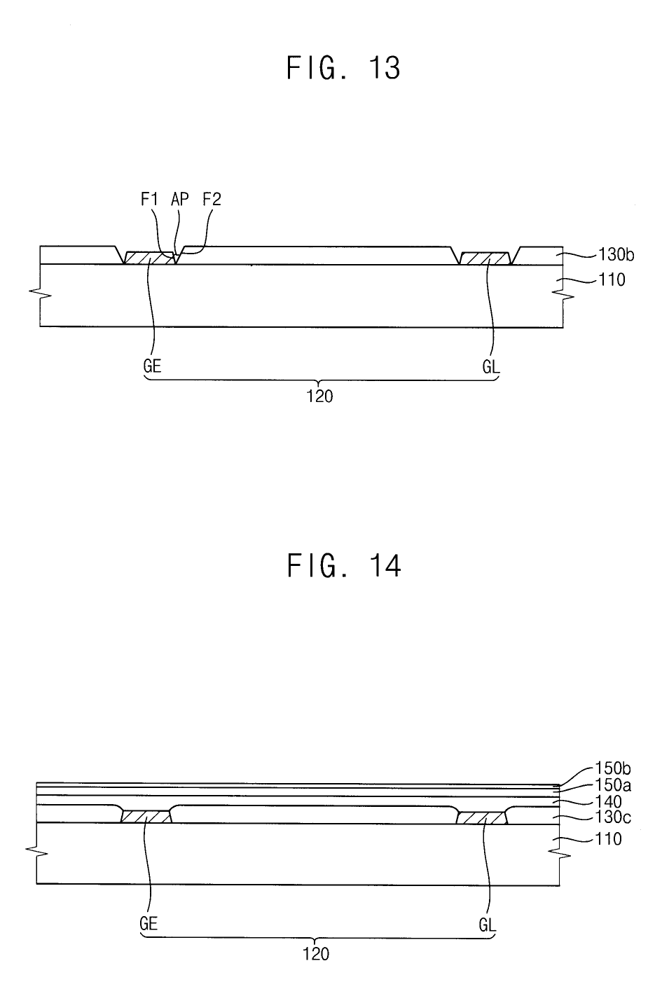

FIG. 9 is a plan view illustrating an exemplary embodiment of an array substrate.

Referring to FIG. 9, the array substrate 100 includes a gate line GL, a data line DL, a TFT switching element, and a pixel electrode PE.

The gate line GL can extend in a first direction D1 of the array substrate 100, and can be aligned in a second direction D2. The first direction D1 can be substantially perpendicular to the second direction D2. The data line DL can extend in the second direction D2, and can be aligned in the first direction D1. A pixel electrode PE can be disposed where a gate line GL crosses a data line DL.

A TFT switching element includes a gate electrode GE, a source electrode SE and a drain electrode DE. The gate electrode GE is in electrical communication with the gate line GL. The source electrode SE is in electrical communication with the data lines DL. The drain electrode DE is spaced apart from the source electrode SE. A contact hole CNT is disposed on a portion of the drain electrode DE, and the drain electrode DE is in electrical communication with the pixel electrode PE through the contact hole CNT so that the TFT switching element is in electrical communication with the pixel electrode PE.

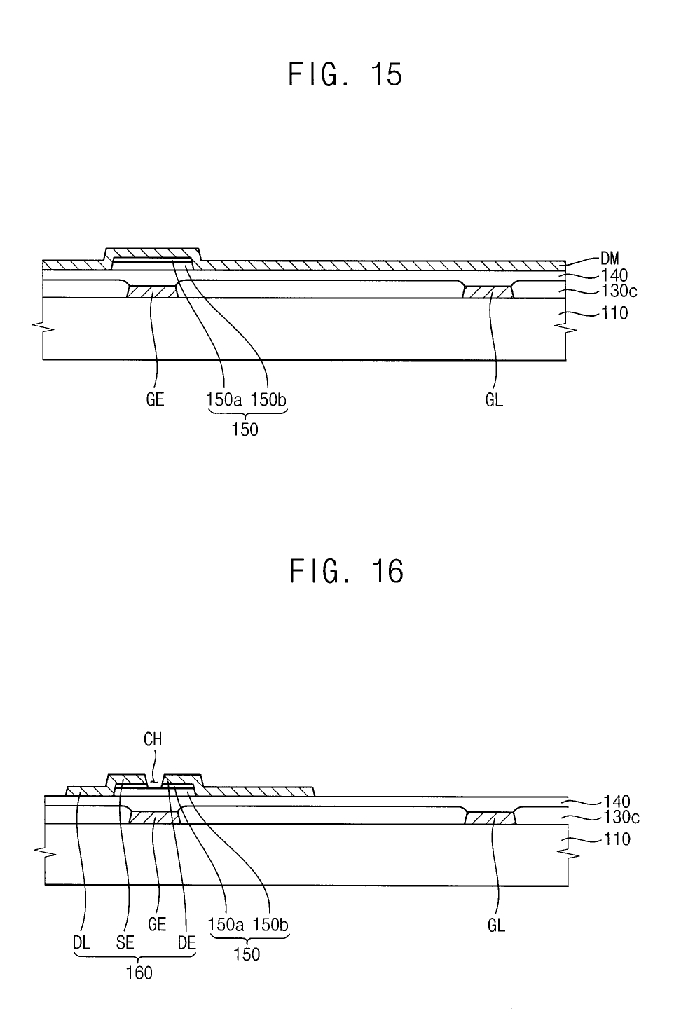

FIG. 10 is a cross-sectional view taken along a line I-I′ shown in FIG. 9.

Referring to FIG. 10, the array substrate 100 of FIG. 9 can further include a gate insulation layer 140 disposed on the base substrate 110 having a gate line GL, a gate electrode GE, a planarization layer 130c, and a semiconductor pattern 150. The data lines DL, the source electrode SE, and the drain electrode DE can be disposed on the base substrate 110 having an ohmic contact layer 150a that is on the gate insulation layer 140. A passivation layer 170 and the pixel electrode PE are disposed on the base substrate 110 having the data lines DL, the source electrode SE, and the drain electrode DE.

The planarization layer 130c can be adjacent to the gate line GL and the gate electrode GE, and the planarization layer 130c can planarize the base substrate 110, the base substrate 110 having the gate line GL and the gate electrode GE. Exemplary materials for the planarization layer 130c include a photoresist, a thermoset, a thermoplastic, or the like, or a combination comprising at least one of the foregoing materials. The planarization layer 130c can have an inclined surface adjacent to the gate lines GL and the gate electrode GE, wherein the inclined surface can be inclined toward a side surface of the gate line GL and/or a side surface of the gate electrode GE. The inclined surface of the planarization layer 130c can form an angle of about 0.01 degrees to about 89 degrees, specifically about 0.1 degrees to about 60 degrees, more specifically about 1 degree to about 50 degrees with respect to the surface of the base substrate 110. A thickness of the planarization layer 130c can be greater than a thickness of the gate lines GL and the gate electrode GE. The planarization layer 130c can planarize the base substrate 110, the base substrate 110 having the gate line GL and the gate electrode GE, thereby increasing the surface uniformity of subsequent layers disposed on the planarization layer 130c.

The gate insulation layer 140 can contact the gate line GL, the gate electrode GE, and/or the planarization layer 130c, and can cover the gate line GL, the gate electrode GE, and the planarization layer 130c. The gate insulation layer 140 can have a uniform surface on the base substrate 110 when disposed on the planarization layer 130c. The semiconductor pattern 150 can include a semiconductor layer 150b on the gate insulation layer 140, and an ohmic contact layer 150a on the semiconductor layer 150b. The passivation layer 170 can be disposed on the base substrate 110, the base substrate 110 having the data lines DL, the source electrode SE, and the drain electrode DE, and can have a contact hole CNT that partially exposes the drain electrode DE. Exemplary materials that can be used for the passivation layer 170 include silicon nitride, silicon oxide, or the like, or a combination comprising at least one of the foregoing materials. An overcoating layer (not shown) can be disposed between the passivation layer 170 and the pixel electrodes PE.

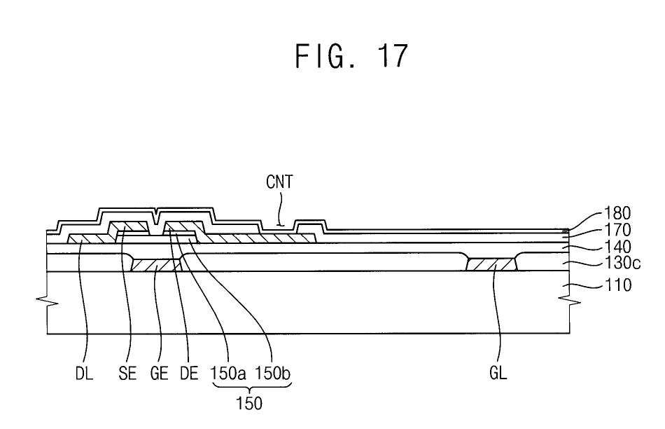

FIGS. 11 to 17 are cross-sectional views illustrating a method of manufacturing the array substrate shown in FIG. 10. The method of planarizing the array substrate of FIGS. 11 to 17 is substantially the same as that shown in FIGS. 1 and 3. Thus, the same reference numerals will be used to refer to the same or like parts as those described in FIGS. 1 and 3 and any redundant explanation concerning the above elements will be omitted.

Referring to FIG. 11, a gate pattern 120 can be disposed on the base substrate 110. The gate pattern 120 can include a gate lines GL and a gate electrode GE.

A gate metal layer (not shown) can be disposed on the base substrate 110, and the gate metal layer can be patterned to form the gate pattern 120. Exemplary methods of patterning the metal layer include photolithography, or the like. Exemplary methods of disposing the gate metal layer on the base substrate 110 include sputtering, vapor deposition, or the like, or a combination comprising at least one of the foregoing methods. Exemplary metals that can be used for the gate metal layer include aluminum (Al), molybdenum (Mo), neodymium (Nd), chromium (Cr), tantalum (Ta), titanium (Ti), tungsten (W), copper (Cu), silver (Ag), or the like, or a combination comprising at least one of the foregoing metals. These metals can be used alone, as an alloy thereof, or as a mixture thereof. The gate metal layer can have a single-layer structure or a multilayer structure. A thickness of the gate metal layer can be about 0.1 μm to about 10 μm, specifically about 0.5 μm to about 5 μm, more specifically 1 μm to about 3 μm.

Referring to FIG. 12, the organic layer 130a can be disposed on the base substrate 110, the base substrate 110 having the gate pattern 120. The organic layer 130a can substantially cover the gate pattern 120 on the base substrate 110. The organic layer 130a can contact the gate pattern 120 and the base substrate 110. In an exemplary embodiment, an organic material can be coated on the base substrate 110, the base substrate 110 having the gate pattern 120. Exemplary coating methods to dispose organic layer 130a include spin-coating, slit coating, or the like, or a combination comprising at least one of the foregoing methods. A thickness of the organic layer 130a can be greater than a thickness of the gate pattern 120.

Referring to FIG. 13, a portion of the organic layer 130a on the gate pattern 120 can be removed to expose the gate pattern 120, thereby disposing the pre-planarization layer 130b that planarizes the surface of the base substrate 110, the base substrate 110 having the gate pattern 120. The side surface F1 of the gate pattern 120 can be spaced apart from the side surface F2 of the pre-planarization layer 130b. The separation part AP is defined between the side surface F1 of the gate pattern 120 and the side surface F2 of the pre-planarization layer 130b.

Exemplary methods for etching the organic layer 130a to dispose the pre-planarization layer 130b include dry-etching, wet etching, or the like. The etching method can be an anisotropic etching method. When the portion of the organic layer 130a on the gate pattern 120 is dry-etched, the upper surface and the side surface F1 of the gate pattern 120 can exposed. The side surface F1 of the gate pattern 120 can be spaced apart from the side surface F2 of the pre-planarization layer 130b. Thus, the separation part AP is defined between the side surface F1 of the gate pattern 120 and the side surface F2 of the pre-planarization layer 130b.

In another embodiment, the organic layer 130a can include photoresist, and the pre-planarization layer 130b can be disposed by exposing the organic layer 130a through a mask, and developing the exposed organic layer 130a. Alternatively, the organic layer 130a can include a photoresist, and light can be irradiated onto the organic layer 130a from a rear surface of the base substrate 110 to expose the organic layer 130a, and the exposed organic layer 130a can be developed to dispose the pre-planarization layer 130b.

Referring to FIG. 14, the pre-planarization layer 130b can be cured to substantially fill the separation part AP using the cured pre-planarization layer 130b to dispose the planarization layer 130c. Exemplary methods of curing the pre-planarization layer 130b include heating the base substrate 110, the base substrate 110 having the pre-planarization layer 130b, in a chamber, irradiating ultraviolet light onto the pre-planarization layer 130b, or the like, or a combination comprising at least one of the foregoing methods.

When the pre-planarization layer 130b is cured, the side surface F2 of the pre-planarization layer 130b can contact the side surface F1 of the gate pattern 120 to dispose the planarization layer 130c. The side surface F2 of the pre-planarization layer 130b can flow toward the side surface F1 of the gate pattern 120 at an angle between about 0.01 degrees to about 89 degrees, specifically about 0.1 degrees and about 60 degrees, more specifically about 1 degree to about 50 degrees.

The gate insulation layer 140, the semiconductor layer 150b, and the ohmic contact layer 150a can be disposed on the base substrate 110 having the planarization layer 130c, in a sequence. Exemplary methods of disposing the gate insulation layer 140, the semiconductor layer 150b, or the ohmic contact layer 150a on the base substrate 110 include chemical vapor deposition (“CVD”), or the like.

The planarization layer 130c can planarize the surface of the base substrate 110, the base substrate 110 having the gate pattern 120, to increase the surface uniformity of a subsequent layer, including the gate insulation layer 140, the semiconductor layer 150b, and the ohmic contact layer 150a. Thus, the gate insulation layer 140, the semiconductor layer 150b, and the ohmic contact layer 150a can be uniformly formed on substantially an entire surface of the base substrate 110.

Exemplary materials for the gate insulation layer 140 include silicon nitride, silicon oxide, or the like, or a combination comprising at least one of the foregoing materials. In an exemplary embodiment, the semiconductor layer 150b can include amorphous silicon (“a-Si”). In an exemplary embodiment, the ohmic contact layer 150a can include an n⁺ amorphous silicon that is implanted by n⁺ impurities.

Referring to FIG. 15, a portion of the semiconductor layer 150b and the ohmic contact layer 150a on the gate electrode GE can be disposed on the gate electrode GE, and a portion of the semiconductor layer 150b and the ohmic contact layer 150a can be removed to dispose the semiconductor pattern 150 having the semiconductor layer 150b and the ohmic contact layer 150a.

A data metal layer DM can be disposed on the base substrate 110, the base substrate 110 having the semiconductor pattern 150. Exemplary methods of disposing the data metal layer DM include sputtering, vapor deposition, or the like, or a combination comprising at least one of the foregoing methods.

Referring to FIG. 16, the data metal layer DM can be patterned to dispose a source pattern 160, the source pattern 160 including a data line DL, a source electrode SE, and a drain electrode DE. A channel part CH partially exposing the semiconductor layer 150a between the source electrode SE and the drain electrode DE can be disposed between the source electrode SE and the drain electrode DE.

Referring to FIG. 17, the passivation layer 170 can be disposed on the base substrate 110, the base substrate having the source pattern 160, and a contact hole CNT can be disposed through the passivation layer 170. Exemplary methods of disposing the contact CNT include photolithography, or the like. Exemplary materials that can be used for the passivation layer 170 include silicon nitride, silicon oxide, or the like, or a combination comprising at least one of the foregoing materials. A transparent electrode layer 180 can be disposed on the passivation layer 170, the passivation layer 170 having a contact hole CNT. The transparent electrode layer 180 can contact the drain electrode DE through the contact hole CNT. The transparent electrode layer 180 can be patterned to dispose a pixel electrode PE. The pixel electrode can comprise a transparent conductive material. Exemplary materials that can be used for the pixel electrode PE include indium tin oxide (“ITO”), indium zinc oxide (“IZO”), or the like, or a combination comprising at least one of the foregoing materials.

In an embodiment, the method of planarizing the substrate, the array substrate and the method of manufacturing the array substrate using the same, a stepped portion between a base substrate and a metal line can be minimized to substantially prevent a stacked structure from forming on a side surface of the metal line and the base substrate. Thus, the surface uniformity of a subsequent layer can be improved, and the reliability of the array substrate and the method of manufacturing the array substrate can be enhanced.

The disclosed embodiments have been described with reference to the exemplary embodiments. While this disclosure describes exemplary embodiments, it will be understood by those skilled in the art in light of the foregoing description that various changes can be made and equivalents can be substituted for elements thereof without departing from the scope of the disclosed embodiments. In addition, many modifications can be made to adapt a particular situation or material to the teachings of this disclosure without departing from the essential scope thereof. Therefore, it is intended that this disclosure not be limited to the particular embodiment disclosed as the best mode contemplated for carrying out this disclosure. Accordingly, the disclosure is intended to include all such alternative modifications and variations as falling within the spirit and scope of the appended claims.

What is claimed is:

1. A method of planarizing a substrate, the method comprising:
disposing an organic layer on a base substrate on which a metal line is formed;
removing a portion of the organic layer to expose an upper surface of the metal line and form a pre-planarization layer, and
wherein a thickness of the organic layer is not less than the metal line.

2. The method of claim 1, further comprising flowing the pre-planarization layer toward a side surface of the metal line to dispose a planarization layer in intimate contact with the side surface of the metal line so that a surface of the base substrate having the metal line is substantially planarized.

3. The method of claim 2, wherein the flowing includes curing the pre-planarization layer.

4. The method of claim 2, wherein an inclined surface is formed by flowing the pre-planarization layer toward the side surface of the metal line, and the inclined surface forms an angle of about 0.1 degrees to about 60 degrees with respect to the surface of the base substrate.

5. The method of claim 1, wherein the pre-planarization layer is disposed by dry-etching the organic layer to decrease a thickness of the organic layer and expose at least a portion of the metal line.

6. The method of claim 1, wherein the organic layer comprises a photoresist.

7. The method of claim 6, wherein the pre-planarization layer is disposed by selectively removing the organic layer using a mask to irradiate a light onto the organic layer to expose the metal line.

8. The method of claim 6, wherein the organic layer comprises a negative photoresist, and
the pre-planarization layer is disposed by:
exposing the negative photoresist layer by irradiating light onto the negative photoresist layer from a rear surface of the base substrate as a mask of the metal line; and
removing the negative photoresist layer to expose the metal line.

9. The method of claim 1, wherein the organic layer is disposed by coating the organic layer on the base substrate.

10. An array substrate comprising:
a gate pattern on a base substrate, the gate pattern including a gate line and a gate electrode in electrical communication with the gate line;
a planarization layer adjacent to and in intimate contact with the gate pattern, the planarization layer having a thickness not less than the gate pattern to planarize a surface of the base substrate having the gate pattern;
a gate insulation layer on the gate pattern and the planarization layer, the gate insulation layer being in intimate contact with an upper surface of the gate pattern and the planarization layer;
a semiconductor pattern on the gate insulation layer;
a source pattern on the gate insulation layer, the source pattern including:
a data line extending in a direction different from a direction of the gate line;
a source electrode on the semiconductor pattern and in electrical communication with the data line; and
a drain electrode on the semiconductor pattern and spaced apart from the source electrode;
a passivation layer on the source pattern, the passivation layer having a contact hole through which the drain electrode is partially exposed; and
a pixel electrode on the passivation layer, the pixel electrode being in electrical communication with the drain electrode through the contact hole.

11. The array substrate of claim 10, wherein the planarization layer comprises:
an inclined surface adjacent to the gate pattern; and
a flat surface extending from the inclined surface.

12. The array substrate of claim 11, wherein the inclined surface forms an angle of about 0.1 degrees to about 60 degrees with respect to the surface of the base substrate.

13. The array substrate of claim 12, wherein a thickness T_{f} of the planarization layer is represented by:
T_{f}=Tₐ+yx tan θ,
wherein Tₐ is a thickness of the gate pattern, and y is a horizontal distance between the gate pattern and an interface between the inclined surface and the flat surface.

14. A method of manufacturing an array substrate, the method comprising:
disposing a gate pattern on a base substrate, the gate pattern including a gate line and a gate electrode in electrical communication with the gate line;
disposing an organic layer on the base substrate, the base substrate including the gate pattern, the organic layer substantially covering the gate pattern;
disposing a pre-planarization layer by removing a portion of the organic layer to expose an upper surface and a side surface of the gate pattern, the pre-planarization layer planarizing a surface of the base substrate;
flowing the pre-planarization layer toward the side surface of the gate pattern to dispose a planarization layer, the planarization layer being in intimate contact with the side surface of the gate pattern;
disposing a source pattern on the base substrate, the base substrate having the gate pattern and the planarization layer, the source pattern including a data line extending in a direction different from the gate line, a source electrode in electrical communication with the data line, and a drain electrode spaced apart from the source electrode; and
disposing a pixel electrode on the base substrate, the base substrate having the source pattern, the pixel electrode being in electrical communication with the drain electrode.

15. The method of claim 14, wherein the flowing includes curing the pre-planarization layer.

16. The method of claim 14, wherein the pre-planarization layer is disposed by dry-etching the organic layer to decrease a thickness of the organic layer so that the gate pattern is exposed.

17. The method of claim 14, wherein the organic layer comprises a photoresist.

18. The method of claim 17, wherein the pre-planarization layer is disposed by selectively removing the organic layer using a mask to expose the gate pattern.

19. The method of claim 17, wherein the organic layer comprises a negative photoresist, and
wherein the pre-planarization layer is disposed by:
exposing a negative photoresist, the exposing comprising irradiating light onto the negative photoresist layer from a rear surface of the base substrate; and
removing the negative photoresist layer to expose the gate pattern.

20. The method of claim 14, wherein an inclined surface is formed by flowing the pre-planarization layer toward the side surface of the gate pattern, and wherein the inclined surface forms an angle of about 0.1 degrees to about 60 degrees with respect to the surface of the base substrate.
